(19) United States
(12) Patent Application Publication
(10) Pub. No.: US 2023/0137675 A1
(43) Pub. Date: May 4, 2023

(54) METHOD FOR MANUFACTURING A LUMINESCENT TIMEPIECE COMPONENT

(71) Applicant: The Swatch Group Research and Development Ltd, Marin (CH)

(72) Inventors: Sophie Napoli, Neuchâtel (CH); Nicolas FRANÇOIS, Neuchâtel (CH)

(73) Assignee: The Swatch Group Research and Development Ltd, Marin (CH)

(21) Appl. No.: 17/817,055

(22) Filed: Aug. 3, 2022

(30) Foreign Application Priority Data
Oct. 29, 2021 (EP) 21205701.2

(51) Int. Cl. B29C 48/00; B29C 48/07

(52) U.S. Cl. CPC B29C 48/022; B29C 48/0022; B29C 48/07; B29K 2033/12

(57) ABSTRACT

A method for manufacturing a luminescent timepiece component for a portable object includes producing a pre-mixture of a phosphorescent pigment in an amount of 10 to 40% by weight, a fluorescent pigment in an amount of 1 to 4% by weight and a plasticiser in a maximum amount of 10% by weight; mixing a polymer base with the pre-mixture and extruding a first time the mixture obtained to obtain a homogeneous polymer mixture; extruding a second time the polymer mixture to form a strip of a predetermined thickness; and cutting the strip to obtain the desired luminescent timepiece component.

### TECHNICAL FIELD OF THE INVENTION

The invention pertains to a method for manufacturing a luminescent timepiece component. The present invention also relates to such a timepiece component obtained from the manufacturing method.

### TECHNOLOGICAL BACKGROUND

The use of photoluminescent materials is fairly widespread on the market and this for varied applications, such as the hands or the indices.

Phosphorescence technology is commonly used in the field of horology via various decoration methods in order to illuminate hands, dials and other components.

Fluorescence technology is also used for the decoration of internal part components via pad printing or spray coating using fluorescent pigments in order to decorate the watch and this in a plurality of colours.

On the other hand, the dials and the hands are usually made of a metal material then, after a plurality of finishing steps, decorated with either a phosphorescent, or fluorescent, ink.

This design has a plurality of drawbacks:
the limitation of luminous performances, the thicknesses of phosphorescent and fluorescent inks are limited to around one hundred microns with the current decoration methods;
a complexification of decoration methods, a white undercoat is sometimes necessary before the phosphorescent decoration in order to have an opaque decoration and maximise performances;
the completely opaque components limiting the design.

### SUMMARY OF THE INVENTION

The aim of the invention is a method for manufacturing a luminescent timepiece component that does not suffer the drawbacks described above.

The present invention relates to a method for manufacturing a luminescent timepiece component for a portable object comprising the steps of:
producing a pre-mixture of a phosphorescent pigment in an amount of 10 to 40% by weight, a fluorescent pigment in an amount of 1 to 4% by weight and a plasticiser in a maximum amount of 10% by weight;
mixing a polymer base with said pre-mixture and extruding a first time the mixture obtained to obtain a homogeneous polymer mixture;
extruding a second time the polymer mixture to form a strip of a thickness of at least 0.3 mm;
cutting the strip to obtain the desired luminescent timepiece component;

In accordance with other advantageous variants of the invention:
the polymer base is a thermoplastic polymer base;
the polymer base is transparent at wavelengths of the near ultra-violet spectrum and at wavelengths of the visible spectrum;
the thermoplastic polymer base is selected from polycarbonate, PMMA, etc.
the extruded strip is cooled at ambient temperature;
the first extrusion is performed via a twin-screw extruder;
the second extrusion is performed via a single-screw extruder;
the strip obtained during the second extrusion is in the form of a strip in two portions, a first portion referred to as upper is formed by the luminescent mixture obtained at the end of the first extrusion, and the second portion referred to as lower portion is formed by a strip made of white polymer material.

The invention also concerns a luminescent timepiece component obtained from such a method.

The invention also concerns a timepiece including at least one such timepiece component.

### DETAILED DESCRIPTION OF THE INVENTION

The present invention relates to a method for manufacturing a luminescent timepiece component for a portable object, as well as the luminescent timepiece component obtained.

Luminescent means that the component is photoluminescent, fluorescent, phosphorescent, or a combination.

Phosphorescent means an element having the property of being able to absorb light and re-emit it at a longer wavelength. The emission persists for some time when the luminous excitation has ceased. The ink contains at least one photoluminescent agent to impart the photoluminescence properties to the ink. Preferably, the luminescent agent is a fluorescent agent. Advantageously, it is selected from inorganic fluorophores and organo-lanthanide complexes. According to another alternative, the fluorescent agent may also be selected from organic fluorophores. It may be, for example, fluorescein, europium 1,3-diphenyl-1,3-propanedionate-1,10-phenantrolin, doped gadolinium oxysulphide, doped magnesium and barium aluminate, doped lithium aluminate, doped strontium molybdate.

Fluorescent means an element having the property of being able to absorb light and re-emit it at a longer wavelength. The emission ceases when the luminous excitation ceases.

The miscellaneous steps of the manufacturing method according to the invention will now be described.

During a first step, a pre-mixture is made of a phosphorescent pigment in an amount of 10 to 40% by weight, of a plasticiser and a fluorescent pigment in an amount of 4% by weight in order to obtain a sufficiently noticeable daylight colour without compromising on the phosphorescent performances. The amount of luminescent particles is selected so as to be sufficient to be able to demarcate the decorated timepiece component and render it easily and immediately visible in the dark. The plasticisers are present in a maximum amount of 10% by weight to subsequently adjust the malleability of the polymer base and thus make it less brittle during manipulations and machining. This pre-mixing makes it possible to coat the pigments, prevent their abrasion and facilitate their incorporation into the polymer base for the remainder of the method. Polyethylenes, paraffins, or also polydimethoxysilanes are commonly used as plasticisers.

Daylight fluorescent pigment is added in an amount of 1 to 4% by weight, which makes it possible to modify the colour visible by day because these fluorescent pigments are coloured. These daylight fluorescent pigments have a daylight colour as opposed to UV Light fluorescent pigments that are of neutral colour in the light of the day but are excited by UV light. They also make it possible to reinforce and modify the phosphorescent effect via an energy conversion. For example, if a Light Blue phosphorescent pigment is used, and a pink fluorescent pigment is added, then the final night emission colour will be pinky/violet. Therefore, it is possible, according to the mixtures made, to make the fluorescent colour visible by day correspond to the phosphorescent colour visible by night.

During the following step, a mixture is made with the pre-mixture and a polymer base, then a first extrusion of the pre-mixture to obtain a homogeneous mixture and distribute the luminescent particles into the polymer base and thus prevent clusters of particles that would be detrimental both to the visual rendering on the timepiece component and to the performances of the luminescent pigments. The base polymer is thus mixed with the pre-mixture based on plasticiser and pigments in order to make sliding between the chains possible.

The polymer base used may be a thermoplastic polymer such as polycarbonate (PC), polyamide (PA), methylmethacrylate acrylonitrile butadiene styrene (MABS), glycolised polyethylene terephthalate (PETg), etc. Advantageously, the polymer base used is both transparent at wavelengths of the near ultra-violet spectrum and at wavelengths of the visible spectrum, this makes better absorption of the light by the pigments possible.

Preferably, the extrusion is performed via a twin-screw extruder so as to obtain a homogeneous mixture and a good dispersion of the pigments. At the end of this first extrusion, the material is generally output in the form of granules, which makes it possible to facilitate the transport and the storage for the remainder of the method.

The material obtained during the first extrusion is subsequently re-extruded on a single-screw extruder equipped with a die for producing calendered strips of a thickness of at least 0.3 mm. The thickness may obviously be brought to vary depending on the timepiece component that it is desired to obtain at the end. It has been noted by the inventors that below a thickness of 0.3 mm, the parts are too fragile and are not strong mechanically. For example, a hand of 0.15 mm is too flexible and has inhomogeneous mechanical performances, the hand not supporting its own weight. Thus, in order to guarantee good performances and a good strength, a minimum thickness of 0.3 mm is desired.

According to one variant of the invention, the profile obtained during the second extrusion is in the form of a strip in two portions, a first portion referred to as upper is formed by the mixture obtained at the end of the first extrusion, and the second portion referred to as lower portion is formed by a strip made of white polymer material. Such an arrangement makes it possible to obtain a reflective coat under the coat made of luminescent material and thus obtain better performances.

There is no upper limitation of thickness. It is possible to produce the thickness of the part directly and to cut the part if the latter is flat. It is also possible to extrude thicker strips and machine the parts after cutting to also correct their thickness. For example, for hands in order to be able to cut the top of the largest hand and a thinner foot. For cost reasons, the die may be adapted to the section of the largest hand in order to extrude its profile.

Once the compound has been re-extruded, the strip is cut, via stamping or laser cutting for example, to obtain the desired luminescent timepiece component.

Finally, a last optional step consists in decorating by printing or etching the timepiece component obtained so that only a luminescent portion of the component is visible.

According to the invention, such a method makes it possible to obtain a luminescent dial or hands.

### EXAMPLE OF EMBODIMENT

A pre-mixture is made by mixing a plasticising agent in a maximum amount of 10% by weight with a photoluminescent pigment in an amount of 10 to 40% by weight (particle size D50: 15-20 μm) and a fluorescent pigment is subsequently added in an amount of 1 to 4% by weight. The plasticising agent makes it possible to improve the solidity of the material, and optimise the phosphorescent pigment-matrix interactions.

A polymer base is subsequently mixed with the pre-mixture.

The mixture is homogenised via a first twin-screw extrusion.

A second extrusion of the compound is subsequently performed to form a strip of a thickness of at least 0.3 mm.

Cooling of the strip at ambient temperature.

Once the strip is formed and cooled, it is cut via laser or stamping in order to obtain the desired timepieces.

1-10. (canceled)

11. A method for manufacturing a luminescent timepiece component for a portable object, the method comprising:
producing a pre-mixture of a phosphorescent pigment in an amount of 10 to 40% by weight, a fluorescent pigment in an amount of 1 to 4% by weight and a plasticiser in a maximum amount of 10% by weight;
mixing a polymer base with said pre-mixture and extruding a first time the mixture obtained to obtain a homogeneous polymer mixture;
extruding a second time the polymer mixture to form a strip of a predetermined thickness; and
cutting the strip to obtain the desired luminescent timepiece component.

12. The manufacturing method according to claim 11, wherein the polymer base is a thermoplastic polymer base.

13. The manufacturing method according to claim 11, wherein the polymer base is transparent at wavelengths of the near ultra-violet spectrum and at wavelengths of the visible spectrum.

14. The manufacturing method according to claim 11, wherein the thermoplastic polymer base is selected from polycarbonate, PMMA.

15. The manufacturing method according to claim 11, wherein the extruded strip is cooled at ambient temperature.

16. The manufacturing method according to claim 11 wherein the first extrusion is performed via a twin-screw extruder.

17. The manufacturing method according to claim 11, wherein the second extrusion is performed via a single-screw extruder.

18. The manufacturing method according to claim 11, wherein the strip obtained during the second extrusion is in the form of a strip in two portions, a first portion referred to as upper is formed by the luminescent mixture obtained at the end of the first extrusion, and the second portion referred to as lower portion is formed by a strip made of white polymer material.

19. The manufacturing method according to claim 11, wherein the luminescent timepiece component formed is a dial or a hand.

20. A luminescent timepiece component obtained via the manufacturing method according to claim 11.
